(19) United States
(12) Patent Application Publication
(10) Pub. No.: US 2009/0071535 A1
(43) Pub. Date: Mar. 19, 2009

(54) ANTIREFLECTIVE COATING ON SOLAR CELLS AND METHOD FOR THE PRODUCTION OF SUCH AN ANTIREFLECTIVE COATING

(75) Inventors: Rainer Moeller, Dresden (DE); Robert Michael Hartung, Blaubeuren (DE); Harald Wanka, Blaustein (DE)

Correspondence Address: HESLIN ROTHENBERG FARLEY & MESITI PC, 5 COLUMBIA CIRCLE, ALBANY, NY, 12203, US

(73) Assignee: Centrotherm Photovoltaics AG, Blaubeuren (DE)

(21) Appl. No.: 12/090,534

(22) PCT Filed: Nov. 2, 2006
(86) PCT No.: PCT/DE2006/001927

§ 371 Date: Nov. 10, 2008

(30) Foreign Application Priority Data
Nov. 2, 2005 (DE) 10 2005 052 556.3

(51) Int. Cl. H01L 31/00

(52) U.S. Cl. 136/256

(57) ABSTRACT

Disclosed is an antireflective coating on solar cells made of crystalline silicon as well as a method for producing such an antireflective coating. The aim is to create an antireflective coating on solar cells made of crystalline silicon which makes it possible to optimize the optical and passivating properties thereof while making it possible to easily and economically integrate the production thereof into the production process especially of very thin crystalline silicon solar cells. The antireflective coating is composed of successive partial layers, i.e., a lower partial layer which covers the crystalline silicon, is embodied as an antireflective coating and as passivation with a particularly great hydrogen concentration, and is covered by an upper partial layer having an increased barrier effect against hydrogen diffusion.

The invention concerns an antireflective coating on solar cells made of crystalline silicon, as well as a method for production of such an antireflective coating.

Antireflective layers on solar cells made of crystalline silicon have the task of causing optimal antireflection of the solar cells in the later solar module and, at the same time, creating the condition for good electrical passivation of the silicon surface, as well as the grain boundaries and defects in silicon.

For antireflective coating of solar cells made of crystalline silicon, mostly silicon nitride is ordinarily used, which is deposited by plasma chemical methods on the front of the solar cells. The method is then conducted so that during silicon nitride deposition, a sufficient amount of hydrogen is simultaneously also incorporated in the SiN layer.

This offers the advantage of surface and bulk passivation of the crystalline silicon solar cells by diffusion of hydrogen into the silicon during a subsequent high-temperature process step, in addition to the primarily sought antireflective effect. Because of this, the efficiency of such solar cells is significantly improved in comparison with solar cells with antireflective layers without this passivating effect.

An example of an antireflective film, but without additional incorporation of hydrogen, is apparent from DE 35 11 675 C2. The antireflective film is applied by reactive sputtering on the silicon, so that the amount of nitrogen is greatest and the amount of oxygen lowest on the side of the interface between the antireflective film and the light-absorbing layer, and that the amount of nitrogen diminishes and the amount of oxygen increases with increasing distance from the interface. An antireflective film with a continuously varying refractive index is formed on this account.

The plasma chemical methods used for production of the antireflective coating (plasma CVD, sputtering) represent very costly vacuum process steps, through which high costs are caused. In addition, simple and easy to handle continuous methods are not applicable without intolerably high vacuum demands (locks). On the other hand, continuous methods are increasingly gaining significance, especially with the increasingly thinner solar cells that are therefore more sensitive to rupture.

In addition, the hydrogen content of the silicon nitride antireflective layers required for good passivation has the drawback in the solar cell production process that “blistering,” i.e., local, conchoidal outbreaks in the silicon layer, are caused in the subsequent high-temperature steps.

This effect can be suppressed by restricting the amount of hydrogen in the layer, on the one hand, to a necessary minimum, and limiting the parameter field of subsequent high temperature steps, on the other. A shortcoming here, however, is that this compromise does not permit optimal layout of these process steps.

In order to achieve the highest possible hydrogen content in the silicon nitride, very loosely constructed layers must necessarily be produced in many methods. However, in the subsequent high temperature steps, in which the hydrogen is supposed to diffuse toward the silicon surface and into the silicon, this means that most of the hydrogen chooses the path of least resistance and diffuses away from the silicon nitride layer from the silicon and therefore is no longer available for passivation of silicon.

The use of silicon nitride is also connected with the drawback that the optical adjustment between silicon of the solar cell (refractive index n=3.88) in the solar module and the cover glass of the solar module (n=1.46) required cannot optimally be achieved, because of its refractive index of n=2-2.1.

The use of multilayer silicon nitride layers or gradient layers with continuously varying refractive index moderates this drawback, but does not completely eliminate it.

More favorable optical properties (n=2.3-2.5) are attainable with titanium dioxide, which can be produced with a simple continuous method. However, titanium dioxide offers no passivation effect.

The underlying task of the invention is to devise an antireflective coating on solar cells made of crystalline silicon, which permits optimal configuration, both of its optical and passivating properties, and whose production can be integrated simply and economically in the manufacturing process, especially of very thin crystalline silicon solar cells.

The task underlying the invention is solved by the fact that the antireflective coating is composed of a succession of partial layers, a lower one of which, the partial layer covering the crystalline silicon as antireflective coating, is formed with particularly high hydrogen content, and that the lower partial layer is covered by an upper partial layer with increased barrier effect against out-diffusion of hydrogen.

The lower partial layer is an amorphous or crystalline Si:H or SiₓN_{y}:H layer, whereas the upper partial layer consists of TiO₂.

The lower partial layer also has a layer thickness of 1-10 nm in the case of an Si:H layer and of 3-10 nm in the case of an SiₓN_{y}:H layers, the layer thickness of both partial layers together amounting to one-fourth of the average wavelength of the average value of sunlight.

Another task underlying the invention is to provide a process for production of such an antireflective coating.

The process according to the invention is characterized by the fact that a lower partial layer that covers the entire surface of the crystalline silicon of the solar cell is deposited on the crystalline silicon in a plasma chemical method at normal pressure with high (maximum possible) hydrogen content as passivation layer, and that an upper partial layer with increased barrier effect against out-diffusion of hydrogen is deposited under normal pressure on the lower partial layer, essentially covering its entire surface.

In a first variant, the lower partial layer is produced in a first furnace part of a continuous furnace, in which the solar cell is exposed to a remote plasma generated at normal pressure at a temperature up to 500° C., which contains one or more process gases with the elements silicon and hydrogen, so that an Si:H layer is produced, and in which the solar cells are then transferred to a second furnace part, in which TiO₂ is deposited to form the upper partial layer at a similar temperature by means of purely thermal normal pressure CVD deposition.

A remote generated plasma is to be understood to mean that the plasma is produced in the plasma chamber, in which no substrates (solar cells to be coated) are situated, in which the elements excited by the plasma are driven from the plasma chamber by a light gas stream onto the substrate being coated.

In a second variant, the lower partial layer is produced in a vacuum apparatus by exposing the solar cell to a plasma from several process gases at a temperature up to 500° C., in which the process gases contain the elements silicon, nitrogen and hydrogen, so that an SiₓN_{y}:H layer is produced, and then transferring the solar cells to a continuous furnace, in which TiO₂ is deposited to form the upper partial layer at a similar temperature by means of purely thermal normal pressure CVD deposition.

In a third variant, the lower partial layer is produced in a vacuum apparatus by exposing the solar cell to a plasma of several process gases at a temperature up to 500° C., in which the process gases contain the elements silicon, nitrogen and hydrogen, so that an SiₓN_{y}:H layer is produced and by then coating the solar cell to form the upper partial layer in another part of the vacuum chamber by a sputtering method with TiO₂.

In a fourth variant, the lower partial layer is produced in a continuous furnace, in which the solar cell is exposed to a remote plasma generated at normal pressure at a temperature up to about 500° C., which contains one or more process gases with the elements silicon, nitrogen and hydrogen, so that an SiₓN_{y}:H layer is produced, and in which the solar cell is then coated with TiO₂ to form the upper partial layer in a vacuum chamber by a sputtering method.

In a continuation of the invention, the lower partial layer is deposited up to a layer thickness of 1-10 nm in the case of an Si:H layer and 3-10 nm in the case of an SiₓN_{y}:H layer, and the upper partial layer then deposited up to a total layer thickness that corresponds to one-fourth of the average wavelength of the average value of sunlight.

Through the solution according to the invention, the possibility is obtained of combining different materials for the partial layers and different layer production methods with each other, so that the optical properties and passivation properties of the resulting layer system can be optimally adjusted separately from each other.

The result is a uniform layer system with a new optical quality with respect to its properties and with respect to its production process.

Separation of the electrical from the optical properties according to the invention by a multilayer system for the passivation and antireflective coating of crystalline silicon solar cells offers another potential. The thin passivation and antireflective coating (lower partial layer) adjacent to the silicon can be optimized with respect to the passivation effect. The transparency of the layer, which is described by the extinction coefficient k1, is of subordinate significance, because of the limited layer thickness. This permits, for example, the use of silicon-rich nitride layers or even amorphous silicon, so that a further improved passivation effect can be achieved.

The invention will now be further explained below on practical examples. In the corresponding drawing figures:

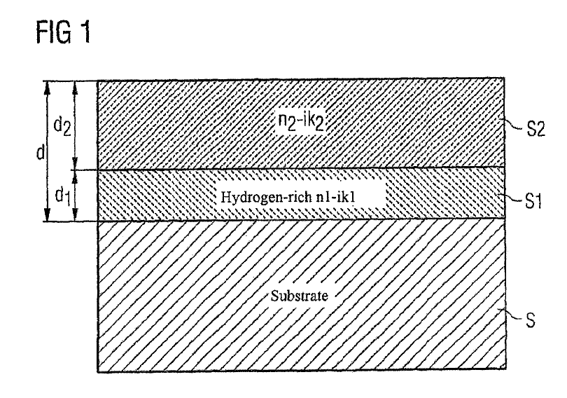

FIG. 1 shows a schematic view of a layer structure on a substrate according to the invention;

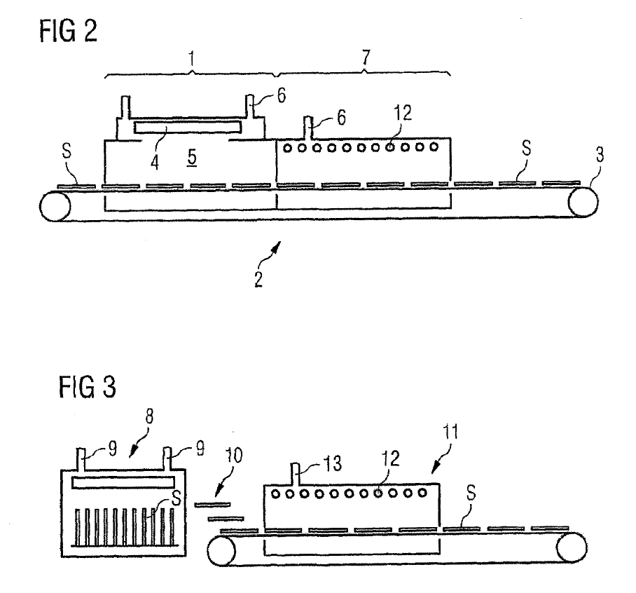

FIG. 2 shows an arrangement for production of a layer structure according to FIG. 1 with a continuous furnace;

FIG. 3 shows an arrangement for production of the layer structure according to FIG. 1 with a vacuum apparatus and subsequent continuous furnace;

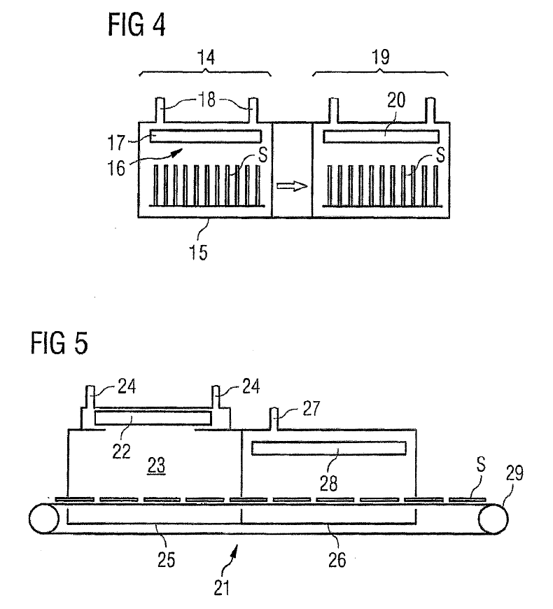

FIG. 4 shows an arrangement for production of a layer structure according to FIG. 1 with a multipart vacuum apparatus; and

FIG. 5 shows an arrangement for production of a layer structure according to FIG. 1 with a multipart evacuable continuous furnace.

The first practical example follows from FIG. 2.

In a first furnace part 1 of a continuous furnace 2, through which the substrates being coated or wafers S (solar cells) pass at a temperature of up to 500° C. by means of a transport device 3, a remote plasma 5, generated at normal pressure by a plasma source 4, is used to excite one or more process gases supplied through process gas feeds 6, which contain the elements silicon and hydrogen. Because of this, a lower partial layer S1 in the form of an amorphous or crystalline Si:H layer with a thickness d₁ of about 1-10 nm is generated on wafer S.

An upper partial layer S2 covering the lower partial layer S1 is then deposited with a thickness d₂ from SiO₂. For this purpose, the wafers S are transferred to a second furnace part 7 of the continuous furnace 1, in which purely thermal normal pressure CVD deposition occurs at a similar temperature, until the desired total layer thickness d=d₁+d₂ of a fourth of the average wavelength of the average value of sunlight is reached.

The resulting layer structure is depicted in FIG. 1.

The second practical example is shown in FIG. 3. Here, the wafers S being coated are exposed in a vacuum apparatus 8 to the plasma of one or more process gases that contain the elements silicon, nitrogen or hydrogen at up to 500° C. The process gases are introduced to the vacuum apparatus 8 through process gas feeds 9. The coating process is then conducted, until a thin lower partial layer S1 in the form of an amorphous or crystalline SiₓN_{y}:H layer is produced with a thickness d₁ of about 3-10 nm.

The wafers S are then [passed through] a continuous furnace 11 by a transport device 10, in which, at a similar temperature, a purely thermal normal pressure CVD deposition of TiO₂ occurs, until an upper partial layer S2 with thickness d₂, up to the desired total layer thickness d of one-fourth of the average wavelength of the average value of sunlight is reached. The continuous furnace 11 is provided for this purpose with a heating device 12 and a process gas feed 13.

A third practical example follows from FIG. 4.

In a first part 14 of a vacuum apparatus 15, the wafers S being coated are exposed at up to 500° C. to the plasma 16 of one or more process gases fed through process gas feeds 18, which contain the elements silicon, nitrogen and hydrogen. The plasma is generated by a plasma source 17. The coating process is continued, until a lower partial layer S1 of SiₓN_{y}:H with a layer thickness d₁ of 3-10 nm is formed.

The wafers S are then coated in a second part 19 of the vacuum apparatus 15 by a sputtering process, preferably with TiO₂, forming the upper partial layer S2 with thickness d₂, until the desired total layer thickness d of one-fourth of the average wavelength of the average value of sunlight is reached. For this purpose, the second part 19 is equipped with a plasma source 20.

A fourth practical example is shown in FIG. 5.

The wafers S being coated are fed through an evacuable continuous furnace 21 at a temperature of up to 500° C., in which a remote plasma 23 generated at normal pressure by a plasma source 22 is used to feed one or more process gases through process gas feeds 24 into a first part 25, which contain the elements silicon, nitrogen and hydrogen, and excite them, in order to produce a lower partial layer S1 of SiₓN_{y}:H with a layer thickness d₁ of 3-10 nm. The upper partial layer S2 with a thickness d₂ is then produced. For this purpose, the wafers S are transferred to a second part 26 of the vacuum chamber and they are coated there, preferably with TiO₂ by a sputtering method, until the desired total layer thickness d of one-fourth the average wavelength of the average value of sunlight is reached. The process gases required for sputtering are fed via a feed 27 into the second part 26, which is provided with a plasma source 28.

Transport of wafers S through the continuous furnace 21 occurs with an appropriate transport device 29, for example, a belt or walking beam device.

### LIST OF REFERENCE NUMBERS

S Substrate/wafer
S1 Lower partial layer
Upper partial layer
1 First furnace part
2 Continuous furnace
3 Transport device
4 Plasma source
5 Plasma
6 Process gas feed
7 Second furnace part
8 Vacuum apparatus
9 Process gas feed
10 Transport device
11 Continuous furnace
12 Heating device
13 Process gas feed
14 First part
15 Vacuum apparatus
17 Plasma source
18 Process gas feed
19 Second part
20 Plasma source
21 Continuous furnace
22 Plasma source
23 Plasma
24 Process gas feed
25 First part
26 Second part
27 Feed
28 Plasma source
29 Transport device

1. Antireflective coating on solar cells made of crystalline silicon, wherein the antireflective coating is composed of consecutive partial layers, a lower partial layer covering the crystalline silicon comprising an antireflective coating and passivation coating with particularly high hydrogen content, the lower partial layer being covered by an upper partial layer with increased barrier effect against out-diffusion of hydrogen.

2. Antireflective coating according to claim 1, wherein the lower partial layer comprises an amorphous or crystalline Si:H or SiₓN_{y}:H layer, and that the upper partial layer comprises TiO₂.

3. Antireflective coating according to claim 2, wherein the lower partial layer has a layer thickness of 1-10 nm in the case of an Si:H layer and of 3-10 nm in the case of an SiₓN_{y}:H layer.

4. Antireflective coating according to claim 2, wherein layer thickness of the lower and the upper partial layers together is one-fourth an average wavelength of an average value of sunlight.

5. Method for production of an antireflective coating on solar cells made of crystalline silicon, wherein a lower partial layer that covers the crystalline silicon of the solar cell over essentially an entire surface is deposited on the crystalline silicon in a plasma chemical method at normal pressure with high hydrogen content as a passivation layer, and on the lower partial layer, an upper partial layer with increased barrier effect against out-diffusion of hydrogen is then deposited at normal pressure, essentially covering an entire surface of the lower partial layer.

6. Method according to claim 5, wherein the lower partial layer is produced in a continuous furnace, in which the solar cell is exposed to a remote plasma generated at normal pressure at a temperature of up to 500° C., which contains one or more process gases with the elements silicon and hydrogen, so that an Si:H layer is produced, and the solar cells is then transferred to a second furnace part, in which, at a similar temperature, TiO₂ is deposited by a purely thermal normal pressure CVD deposition to form the upper partial layer.

7. Method according to claim 5, wherein the lower partial layer is produced in a vacuum apparatus by exposing the solar cell to a plasma of several process gases at a temperature of up to 500° C., in which the process gases contain the elements silicon, nitrogen and hydrogen, so that an SiₓN_{y}:H layer is produced, and the solar cell is then transferred to a continuous furnace, in which TiO₂ is deposited to form the upper partial layer at a similar temperature by purely thermal normal pressure CVD deposition.

8. Method according to claim 5, wherein the lower partial layer is produced in a vacuum apparatus by exposing the solar cell to a plasma of several process gases at a temperature up to 100° C., in which the process gases contain the elements silicon, nitrogen and hydrogen, so that an SiₓN_{y}:H layer is produced, and that the solar cell is then coated to form the upper partial layer in another part of the vacuum chamber by a sputtering method with TiO₂.

9. Method according to claim 5, wherein the lower partial layer is produced in a continuous furnace, in which the solar cell is exposed to a remote plasma generated at normal pressure at a temperature up to approx. 500° C., which contains one or more process gases with the elements silicon, nitrogen and hydrogen, so that an SiₓN_{y}:H layer is produced, and that the solar cell is then coated with TiO₂ to form the upper partial layer in a vacuum chamber by a sputtering method.

10. Method according to claim 5, wherein the lower partial layer is deposited up to a layer thickness of 1-10 nm in a case of a Si:H layer and 3-10 nm in the case of a SiₓN_{y}:H layer, and the upper layer is then deposited to a total layer thickness that corresponds to one-fourth of an average wavelength of an average value of sunlight.
